(19) United States
(12) Patent Application Publication
(10) Pub. No.: US 2026/0112830 A1
(43) Pub. Date: Apr. 23, 2026

(54) BOARD-TO-BOARD CONNECTOR WITH A SHIELDING STRUCTURE

(71) Applicant: WNC Corporation, HSINCHU (TW)

(72) Inventors: YING-CHIH LIU, HSINCHU (TW); CHE-MING WANG, HSINCHU (TW); MING-WEI CHENG, HSINCHU (TW)

(21) Appl. No.: 19/308,373

(22) Filed: Aug. 25, 2025

(30) Foreign Application Priority Data
Oct. 17, 2024 (TW) 113139442

(51) Int. Cl. H01R 12/73; H01R 13/6594; H01R 13/6596

(52) U.S. Cl. CPC H01R 12/737; H01R 13/6594; H01R 13/6596

(57) ABSTRACT

A board-to-board connector assembly with a shielding structure includes a first circuit board, a first connector, a buffering conductor, a second circuit board, a second connector, and a shielding cover. The buffering conductor surrounds the first connector. The second circuit board is perpendicular to the first circuit board. A side edge of the second circuit board is provided with a first metal layer. The second connector is configured to be mated with the first connector along a mating direction. The shielding cover is disposed on the second circuit board and surrounds the second connector. When the second connector is mated with the first connector along the mating direction, the side edge of the second circuit board abuts against the buffering conductor, such that the first metal layer is electrically connected to the buffering conductor, and the shielding cover encloses the first connector.

### CROSS-REFERENCE TO RELATED PATENT APPLICATION

This application claims the benefit of priority to Taiwan Patent Application No. 113139442, filed on October 17, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a board-to-board connector assembly, and more particularly to a board-to-board connector assembly with a shielding structure.

### BACKGROUND OF THE DISCLOSURE

Existing board-to-board connectors are widely used in next generation Wi-Fi^{®} and 5G products. RF signals can be transmitted between two PCBs through the connection provided by the board-to-board connectors (also referred to as BTB connectors).

RF signals are easily interfered by external signals during transmission between BTB connectors. In the related art, a shielding cover is typically used to cover the BTB connectors in order to mitigate signal interference. However, for certain types of BTB connectors such as vertically mated BTB connectors, the shielding cover cannot cover each side of the vertically mated BTB connectors. For example, a side of the connector that connects to the circuit board cannot be shielded by the shielding cover, resulting in a gap in signal shielding.

Therefore, how to overcome the above-mentioned problem through an improvement in structural design has become an important issue to be addressed in the related art.

### SUMMARY OF THE DISCLOSURE

In response to the above-referenced technical inadequacy, the present disclosure provides a board-to-board connector assembly with a shielding structure, so as to address an issue that the existing board-to-board connectors cannot be completely covered by the shielding cover, thereby resulting in a gap in signal shielding.

In order to solve the above-mentioned problems, one of the technical aspects adopted by the present disclosure is to provide a board-to-board connector assembly with a shielding structure, which includes a first circuit board, a first connector, a buffering conductor, a second circuit board, a second connector, and a shielding cover. The first connector is disposed on the first circuit board. The buffering conductor is disposed on the first circuit board and surrounds the first connector. The second circuit board is perpendicular to the first circuit board. A side edge of the second circuit board is provided with a first metal layer. The second connector is disposed on the second circuit board. The second connector is configured to be mated with the first connector along a mating direction. The shielding cover is disposed on the second circuit board and surrounds the second connector. When the second connector is mated with the first connector along the mating direction, the side edge of the second circuit board abuts against the buffering conductor, such that the first metal layer is electrically connected to the buffering conductor, and the shielding cover encloses the first connector.

Therefore, in the board-to-board connector assembly with a shielding structure provided by the present disclosure, through disposing the first metal layer on the side of the second circuit board in cooperation with the shielding cover, the first metal layer is electrically connected to the buffering conductor when the first connector is mated with the second connector, and the shielding cover surrounds the first connector. As a result, the first metal layer can overcome the conventional inability of the shielding cover to fully enclose the connector. The first metal layer and the shielding cover jointly surround the first connector and the second connector, so as to provide complete shielding against external electromagnetic interference.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a board-to-board connector assembly according to an embodiment of the present disclosure;

FIG. 2 is a schematic exploded view of the board-to-board connector assembly according to the embodiment of the present disclosure;

FIG. 3 is a schematic exploded view of a first connector and a buffering conductor according to the embodiment of the present disclosure;

FIG. 4 is a schematic top view of the first connector and the buffering conductor according to the embodiment of the present disclosure;

FIG. 5 is a schematic view of a second connector and a shielding cover according to the embodiment of the present disclosure;

FIG. 6 is a schematic exploded view of the second connector and the shielding cover according to the embodiment of the present disclosure;

FIG. 7 is a schematic top view of the second connector and the shielding cover according to the embodiment of the present disclosure;

FIG. 8 is a schematic bottom view of a second circuit board according to the embodiment of the present disclosure;

FIG. 9 is a schematic side view of the second circuit board according to the embodiment of the present disclosure; and

FIG. 10 is a schematic cross-sectional view taken along line X-X of FIG. 1.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Embodiment]

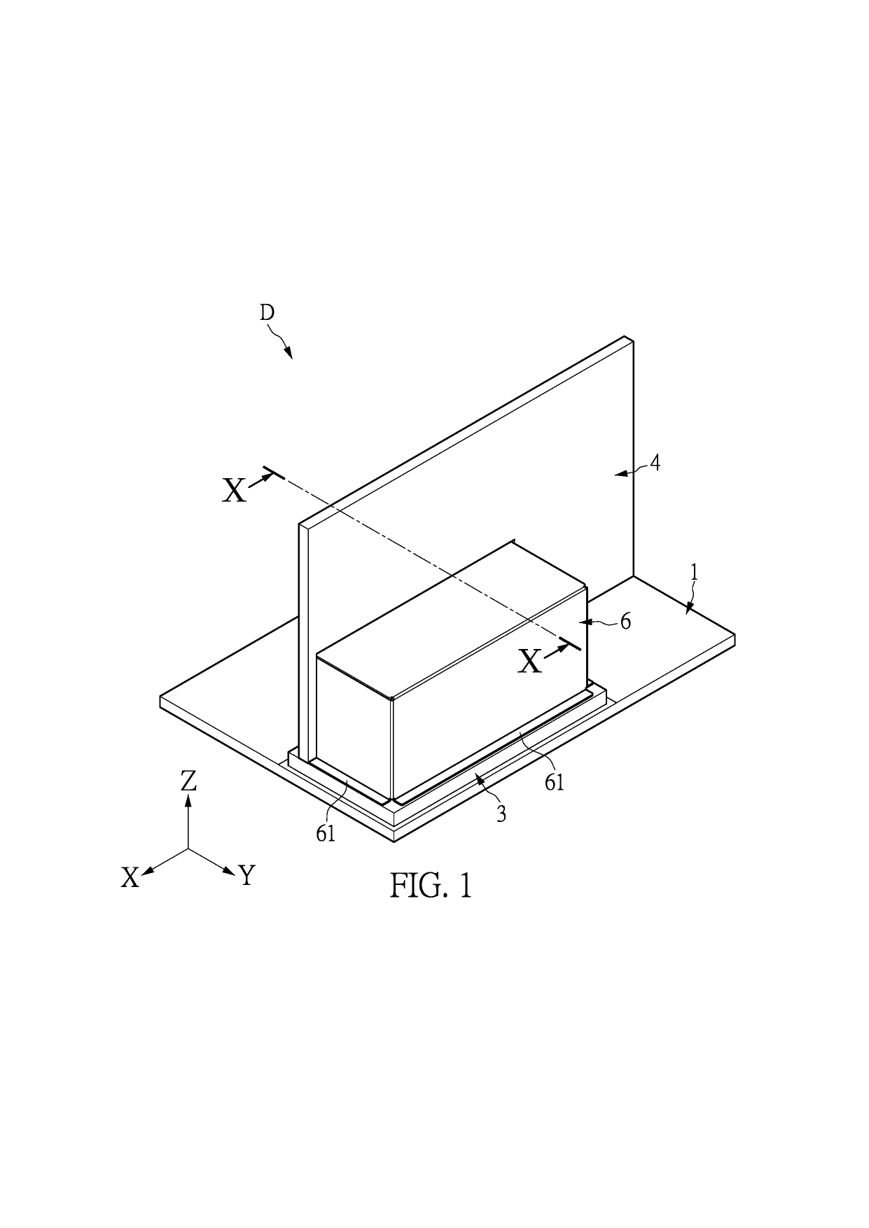

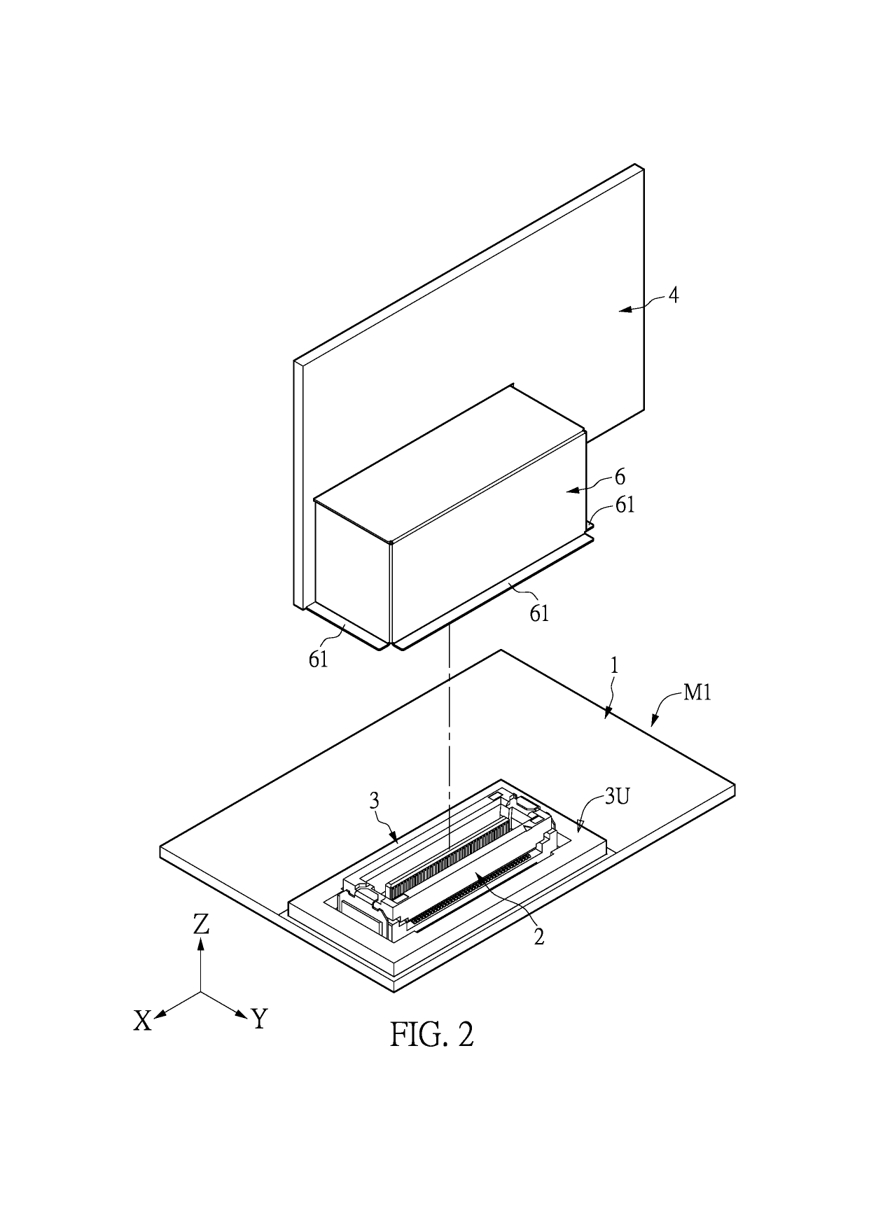

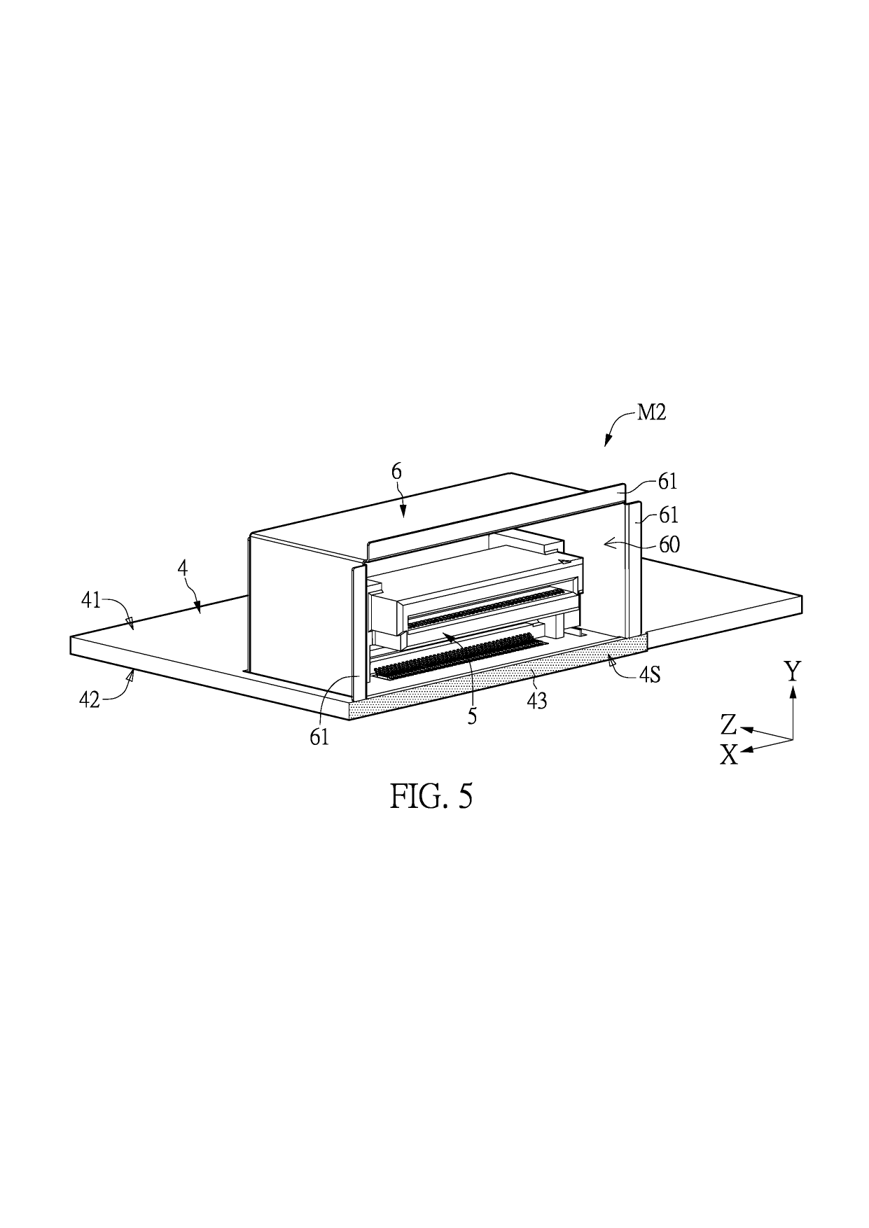

Reference is made to FIGS. 1, 2, and 5. FIG. 1 is a schematic view of a board-to-board connector assembly according to an embodiment of the present disclosure. FIG. 2 is a schematic exploded view of the board-to-board connector assembly according to the embodiment of the present disclosure. FIG. 5 is a schematic view of a second connector and a shielding cover according to the embodiment of the present disclosure. The present disclosure provides a board-to-board connector assembly D with a shielding structure, which includes a first circuit board 1, a first connector 2, a buffering conductor 3, a second circuit board 4, a second connector 5, and a shielding cover 6.

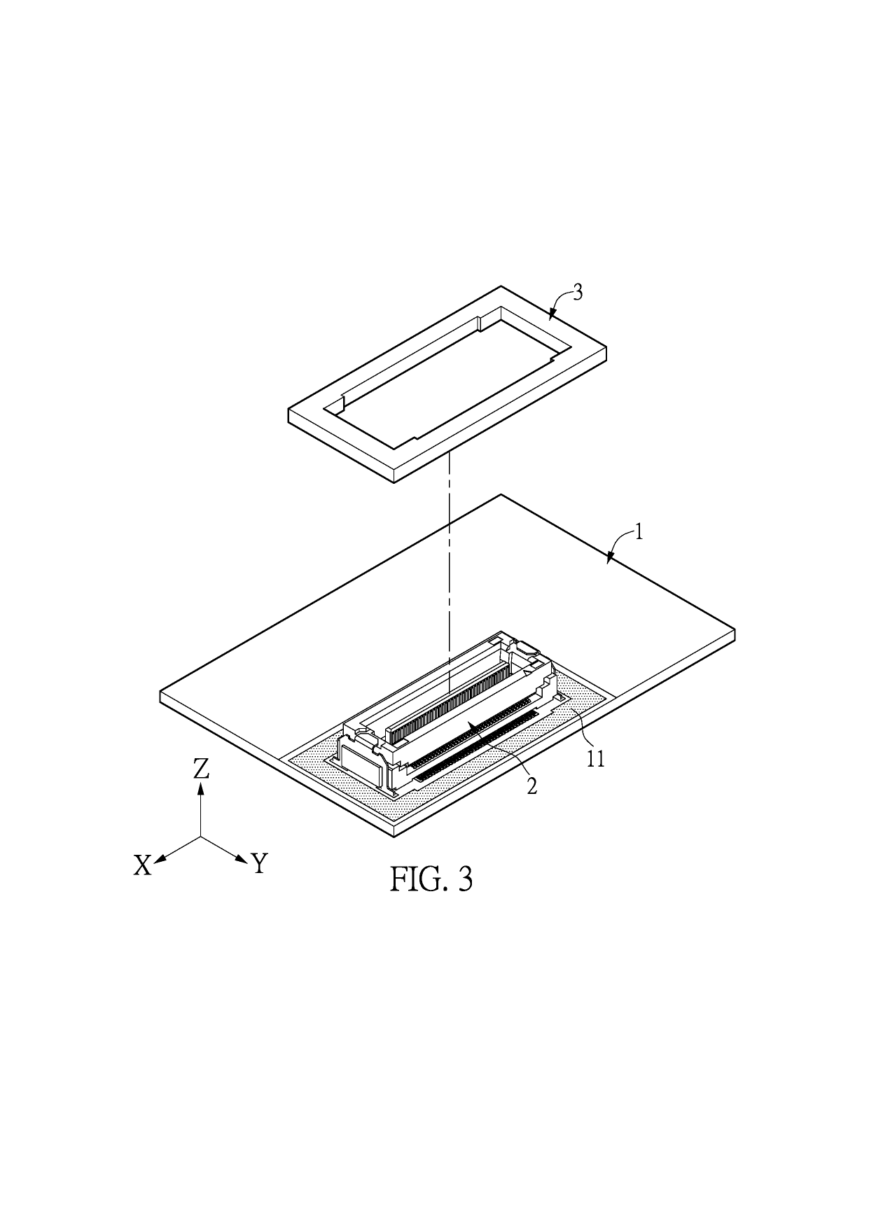

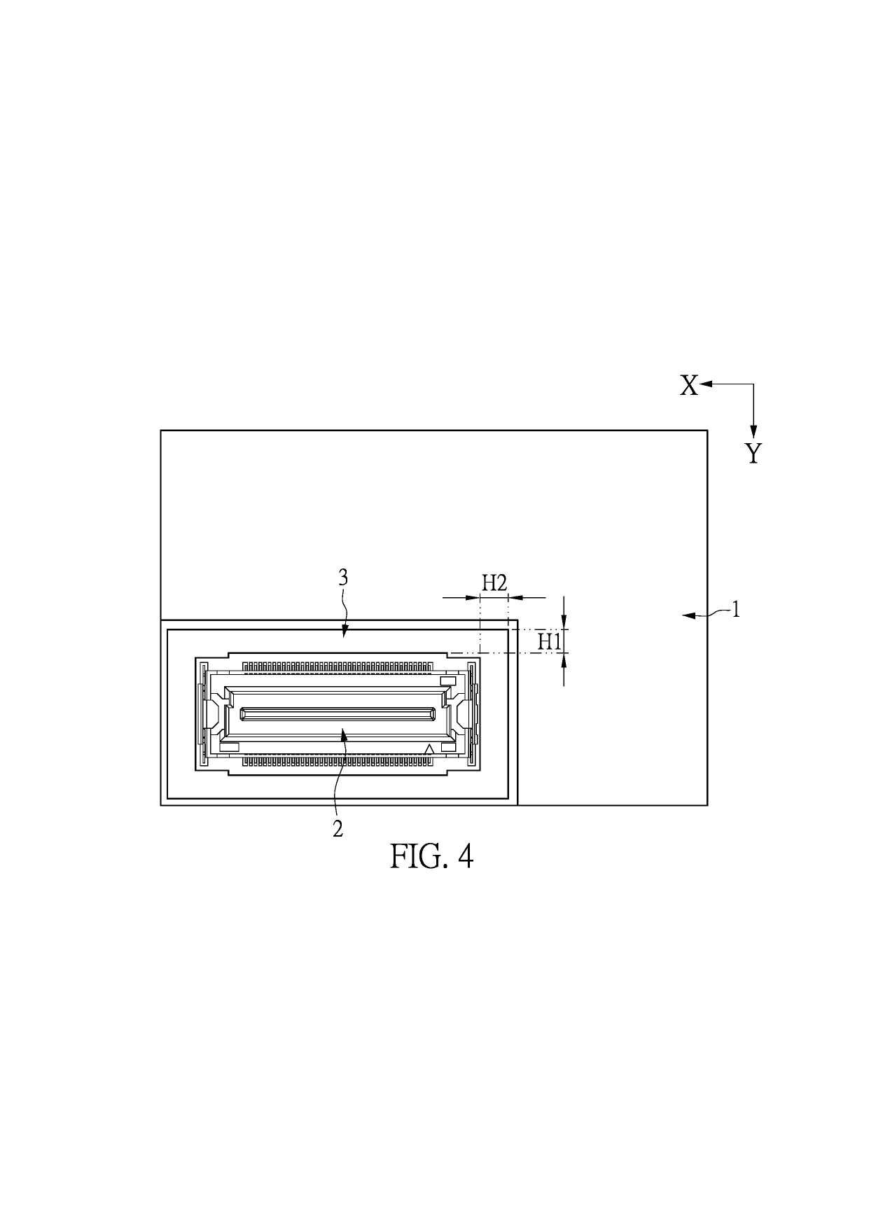

Reference is made to FIGS. 3 and 4. FIG. 3 is a schematic exploded view of a first connector and a buffering conductor according to the embodiment of the present disclosure. FIG. 4 is a schematic top view of the first connector and the buffering conductor according to the embodiment of the present disclosure. The first connector 2 and the buffering conductor 3 are disposed on a surface of the first circuit board 1. For example, the first connector 2 can be soldered onto the first circuit board 1 by surface-mount technology (SMT). As shown in FIG. 3, the surface of the first circuit board 1 has a metal grounding layer 11, which can be an annular exposed copper area. The metal grounding layer 11 surrounds the first connector 2. The buffering conductor 3 is an annular structure corresponding in shape to the metal grounding layer 11. For instance, the buffering conductor 3 can be formed from a compressible conductive material, such as conductive foam or conductive silicone, but the present disclosure is not limited thereto. The buffering conductor 3 is disposed on the metal grounding layer 11, and the buffering conductor 3 is adhered to the metal grounding layer 11 using a conductive adhesive or a conductive tape, thereby surrounding the first connector 2.

Furthermore, the metal grounding layer 11 and the first connector 2 are separated from each other by a predetermined distance, such that the metal grounding layer 11 and the buffering conductor 3 adhered thereon are electrically insulated from the first connector 2. Preferably, the predetermined distance is at least greater than 1 mm. Additionally, a width of the metal grounding layer 11, such as a transverse width H1 that is parallel to an X-axis or a longitudinal width H2 that is parallel to a Y-axis in FIG. 4, is preferably at least greater than 1 mm. In a preferred embodiment, the width H1 is 2.5 mm and the width H2 is 3 mm.

As shown in FIGS. 2 and 5, the second connector 5 and the shielding cover 6 are disposed on the second circuit board 4. For example, the second connector 5 and the shielding cover 6 can be soldered onto the second circuit board 4 using SMT. The shielding cover 6 encloses the second connector 5, and the shielding cover 6 has an opening 60. Specifically, the board-to-board connector assembly D includes a first board-end connector M1 and a second board-end connector M2. The first board-end connector M1 includes the first circuit board 1, the first connector 2, and the buffering conductor 3. The second board-end connector M2 includes the second circuit board 4, the second connector 5, and the shielding cover 6. For example, the first connector 2 can be a female connector, and the second connector 5 can be a male connector, but the present disclosure is not limited thereto. That is, in other embodiments, the first connector 2 can be a male connector, and the second connector 5 can be a female connector.

As shown in FIG. 2, the second board-end connector M2 can be mated with the first board-end connector M1 along a mating direction (i.e., a negative Z-axis direction). During mating, the second circuit board 4 is perpendicular to the first circuit board 1, and the opening 60 of the shielding cover 6 faces the first connector 2, such that the shielding cover 6 can simultaneously cover both the first connector 2 and the second connector 5 during mating, and further abut against the buffering conductor 3. The shielding cover 6 is a metallic housing, which is configured to block external signals. Specifically, the shielding cover 6 can be electrically connected to the metal grounding layer 11 through the buffering conductor 3 to achieve grounding and electrical shielding, thereby preventing external signal interference during transmission between the first connector 2 and the second connector 5, and also preventing signals transmitted between the first connector 2 and the second connector 5 from interfering with nearby electronic components.

The second circuit board 4 has a side edge 4S and two surfaces, a first surface 41 and a second surface 42, which are opposite to each other. The side edge 4S is connected between the first surface 41 and the second surface 42. The side edge 4S of the second circuit board 4 is provided with a first metal layer 43, and the first metal layer 43 is located at an edge of the opening 60. For example, the first metal layer 43 can be an exposed copper layer. Furthermore, the shielding cover 6 includes an extension tab 61 extending from the edge of the opening 60, and the extension tab is bent outward from the opening 60. A quantity of the extension tab 61 is not limited in the present disclosure. For example, the extension tab 61 can be disposed on one side of the opening 60, or alternatively, the plurality of extension tabs 61 can be disposed on three sides of the opening 60. In the embodiment of the present disclosure, the extension tabs 61 are provided on three sides of the opening 60. In other words, the extension tabs 61 extend along the periphery of the opening 60 and surround the opening 60.

As shown in FIGS. 1, 2, and 5, when the shielding cover 6 is disposed on the second circuit board 4, the extension tabs 61 are flush with the side edge 4S of the second circuit board 4 and aligned with the first metal layer 43 (in FIG. 5). When the second connector 5 is mated with the first connector 2, the portion of the second circuit board 4 having the first metal layer 43 on its side edge 4S abuts an upper surface 3U of the buffering conductor 3, such that the first metal layer 43 is electrically connected to the buffering conductor 3. The shielding cover 6 encloses the first connector 2, and its extension tabs 61 abut against the upper surface 3U of the buffering conductor 3, such that the shielding cover 6 is electrically connected to the buffering conductor 3. In a preferred embodiment, when the extension tabs 61 abut against the upper surface 3U, projections of the extension tabs 61 that is projected onto the upper surface 3U does not exceed outside an area of the upper surface 3U (in FIG. 1).

Through structural design of the first metal layer 43 on the side edge of the second circuit board 4 in cooperation with the shielding cover 6, the first metal layer 43 and the shielding cover 6 jointly enclose the first connector 2 and the second connector 5, such that the first metal layer 43 and the extension tabs 61 of the shielding cover 6 jointly form a closed loop. As such, when the first connector 2 is mated with the second connector 5, the first metal layer 43 and the shielding cover 6 are electrically connected to the buffering conductor 3, and further grounded through the metal grounding layer 11, thereby achieving electrical shielding. In the related art, since the connectors (i.e., the first connector 2 and the second connector 5) of the board-end connectors (i.e., the first board-end connector M1 and the second board-end connector M2) are disposed at the edge of the circuit boards, the shielding cover cannot fully enclose the connectors, resulting in shielding gaps in the board-end connectors facing the circuit boards. Therefore, through the structural design of the first metal layer 43 on the side edge of the second circuit board 4 in cooperation with the shielding cover 6, the first metal layer 43 and the shielding cover 6 jointly enclose the first connector 2 and the second connector 5, so as to enhance the effect of electrical shielding and address the issue in the related art where mere reliance on the shielding cover for shielding tends to result in signal interference gaps.

Furthermore, the extension tabs 61 of the shielding cover 6 can enlarge the contact area with the buffering conductor 3, which not only enhances the structural strength of the shielding cover 6 on the buffering conductor 3, but also increases the electrical contact area between the shielding cover 6 and the buffering conductor 3, thereby enhancing the shielding effect. Moreover, since the buffering conductor 3 is compressible, the second circuit board 4 moves downward during mating of the second connector 5 with the first connector 2 and contacts the buffering conductor 3. The buffering conductor 3 is compressed and provides a buffering stroke to prevent direct contact with the first circuit board 1, so as to avoid mechanical interference and ensure stable mating between the second connector 5 and the first connector 2.

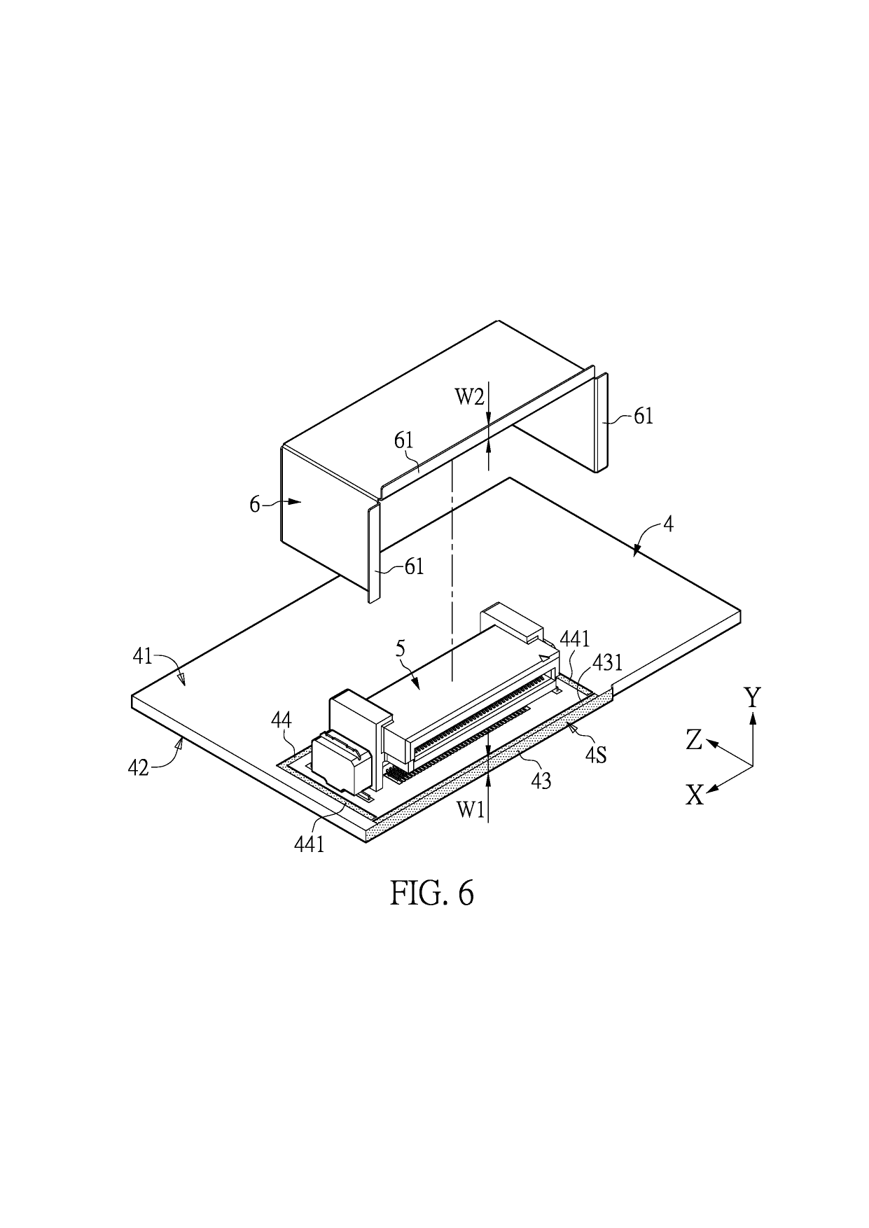

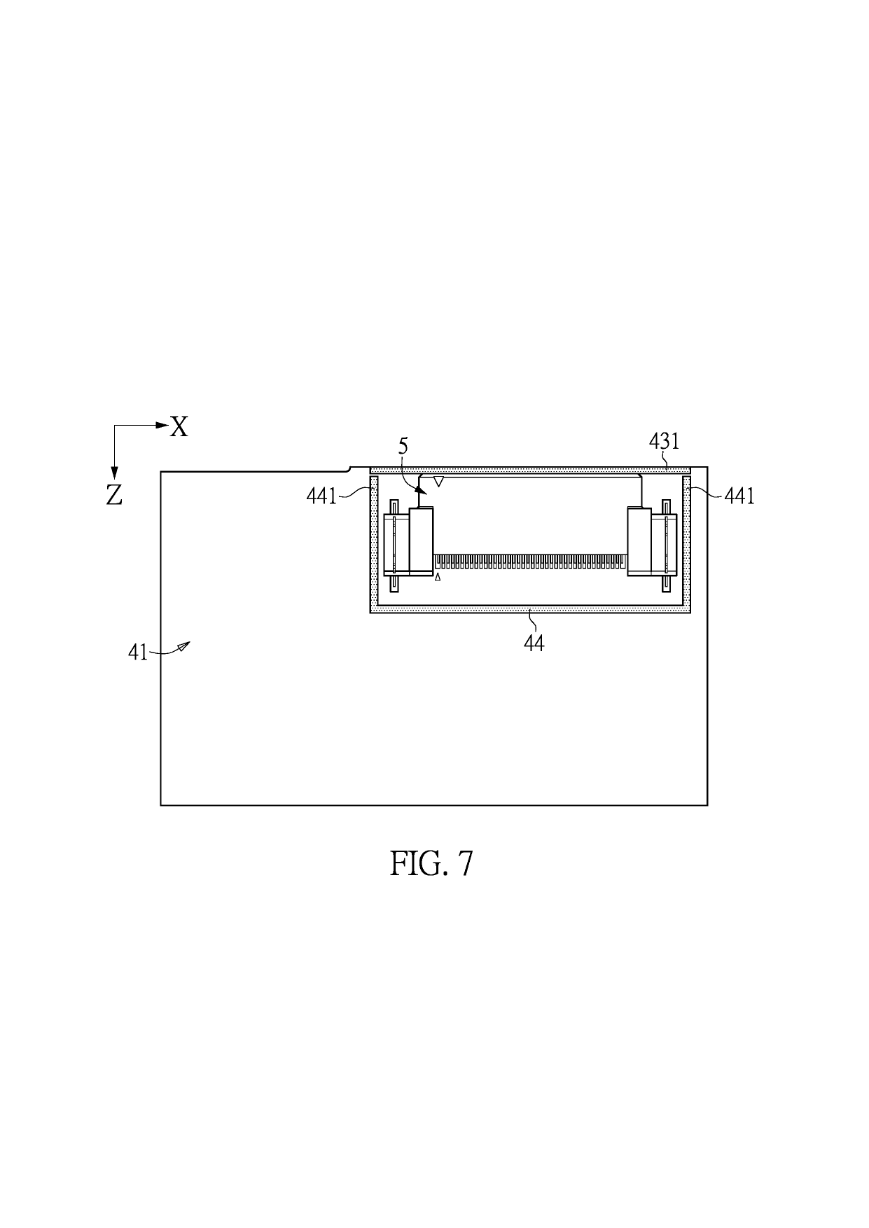

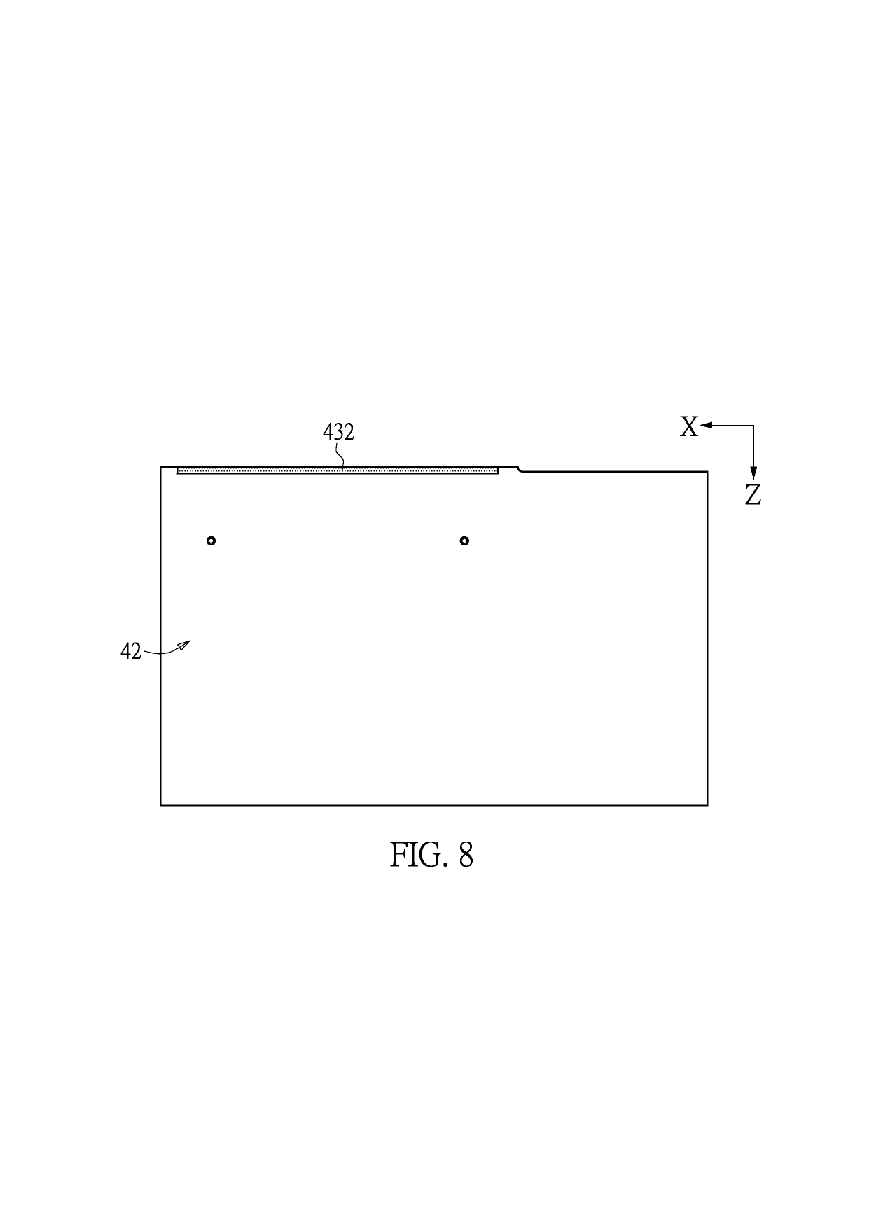

Reference is made to FIGS. 6 to 8. FIG. 6 is a schematic exploded view of the second connector and the shielding cover according to the embodiment of the present disclosure. FIG. 7 is a schematic top view of the second connector and the shielding cover according to the embodiment of the present disclosure. FIG. 8 is a schematic bottom view of a second circuit board according to the embodiment of the present disclosure. A width of the first metal layer 43 should not be too narrow to ensure sufficient contact area with the buffering conductor 3 and maintain effective electrical shielding. As shown in FIG. 6, preferably, the width W1 of the first metal layer 43 is within ±20% of the width W2 of the extension tab 61. For example, the width W1 is 1.6 mm and the width W2 is 1.8 mm. As such, the widths of the contact surfaces between the first metal layer 43 and the buffering conductor 3, and between the shielding cover 6 and the buffering conductor 3, can be substantially uniform at various positions, so that no weak spots are formed in the electrical shielding coverage, thereby avoiding areas with reduced electrical shielding effectiveness. As shown in FIGS. 7 and 8, the first metal layer 43 further includes a first metal extending portion 431 and a second metal extending portion 432. The first metal extending portion 431 extends to the first surface 41 of the second circuit board 4, and the second metal extending portion 432 extends to the second surface 42 of the second circuit board 4. Preferably, the width of the first metal extending portion 431 and the width of the second metal extending portion 432 each range from 0.5 mm to 1 mm.

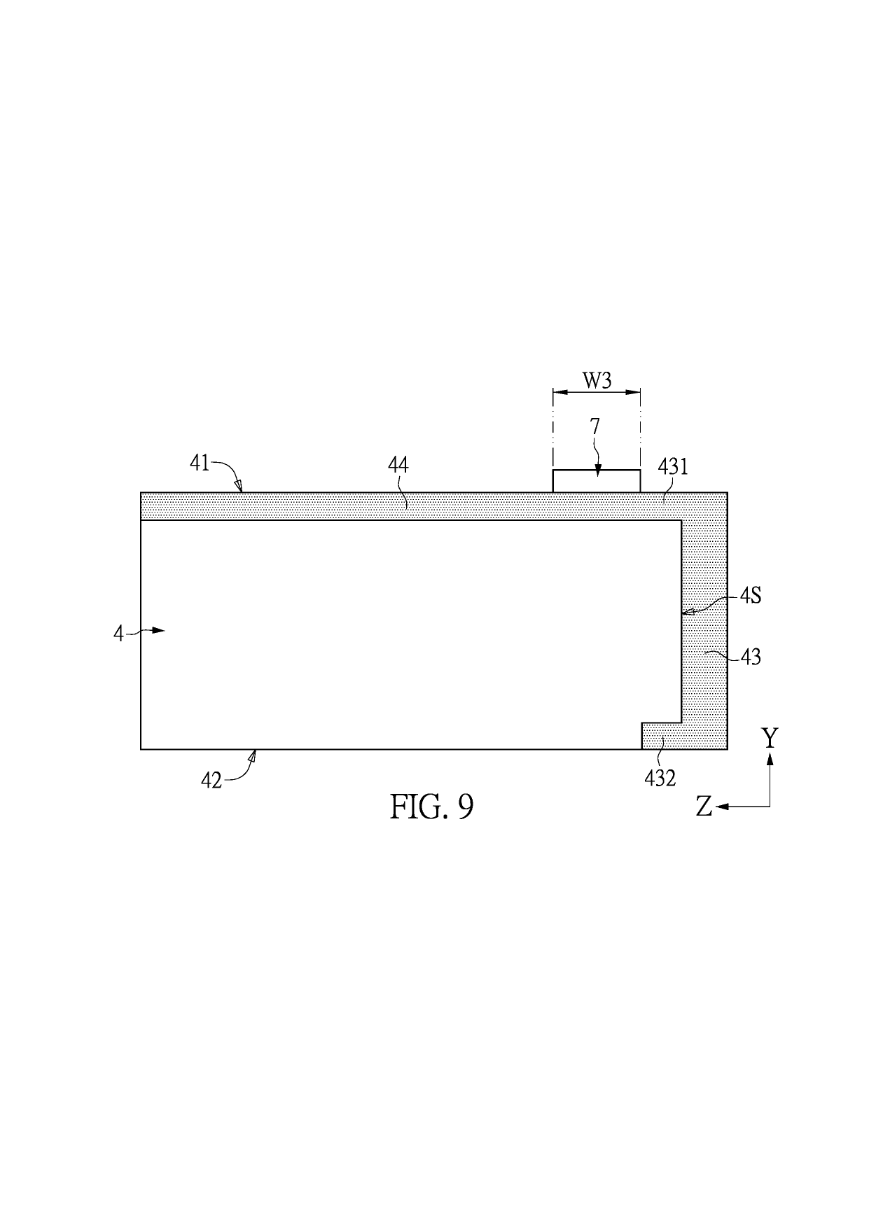

Referring to FIGS. 7 and 9, FIG. 9 is a schematic side view of the second circuit board according to the embodiment of the present disclosure. The second circuit board 4 further includes a second metal layer 44, which is disposed on the first surface 41. As shown in FIG. 7, the second metal layer 44 is a C-shaped exposed copper layer. More specifically, the second metal layer 44 serves as a soldering region for mounting the shielding cover 6. In one embodiment, the second metal layer 44 is elongated and surrounds the second connector 5. Moreover, the second metal layer 44 has two ends 441 (in FIG. 7), and a solder resist layer 7 is provided between a surface of each of the ends 441 and a surface of the first metal layer 43. Specifically, in a preferred embodiment, the solder resist layer 7 is provided between a surface of each of the ends 441 and a surface of the first metal extending portion 431 (in FIG. 9). The solder resist layer 7 is an insulating coating applied to the surface of the second circuit board 4. Preferably, a width W3 of the solder resist layer 7 is greater than 0.1 mm. The solder resist layer 7 is designed to prevent solder (not shown in the figures) located on the second metal layer 44 from extending to the first metal layer 43, so as to prevent the cured solder from interfering with the buffering conductor 3 when the second circuit board 4 contacts the buffering conductor 3, which results in surface unevenness and adversely affects the stability of the mating between the second connector 5 and the first connector 2.

It should be noted that the second metal layer 44 is connected to the first metal layer 43. From the perspective shown in FIG. 7, the second metal layer 44 and the first metal extending portion 431 appear to be disconnected from and do not contact each other. However, from the perspective in FIG. 9, the second metal layer 44 and the first metal extending portion 431 are actually connected to achieve electrical connectivity. In other words, the shielding cover 6 can be electrically connected to the first metal layer 43 through the second metal layer 44, such that both the shielding cover 6 and the first metal layer 43 are in electrical contact with the buffering conductor 3.

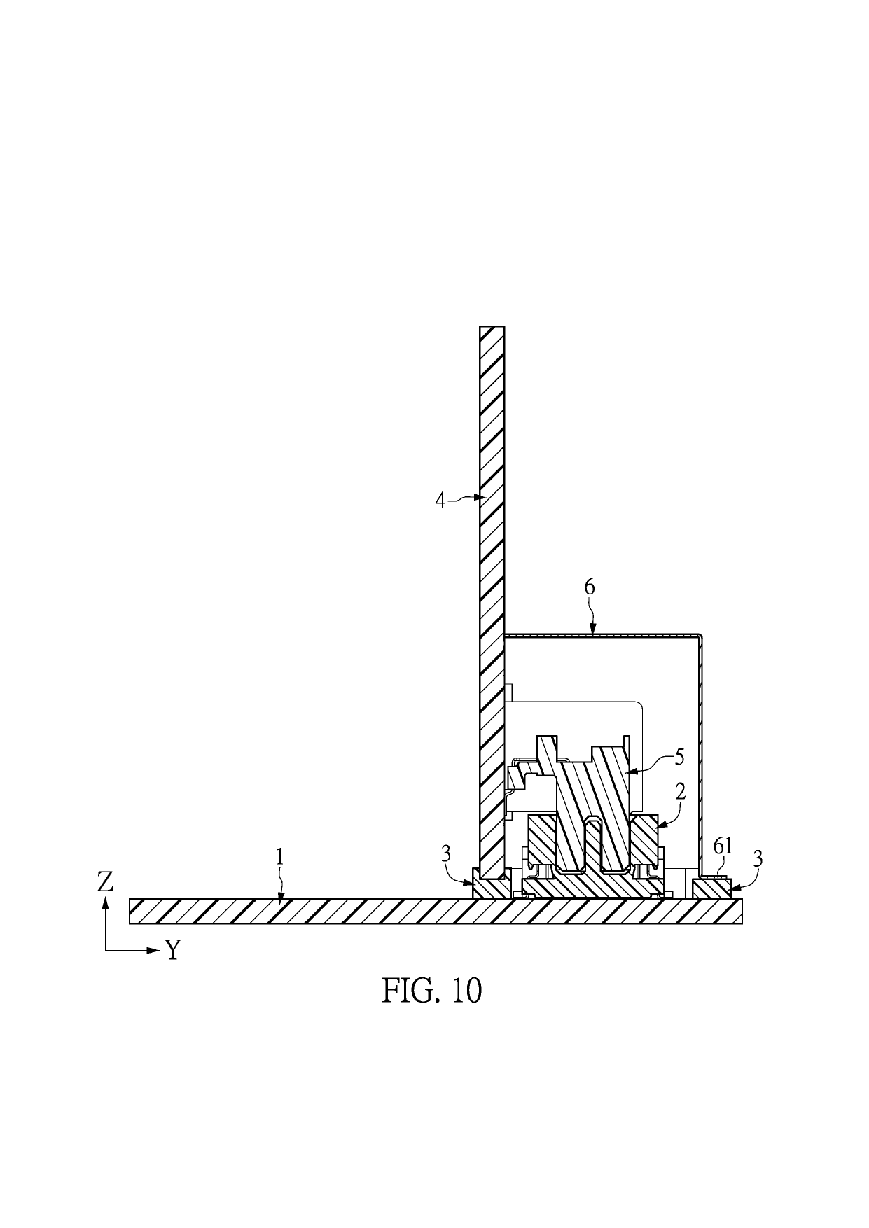

Reference is made to FIGS. 1, 5, and 10. FIG. 10 is a schematic cross-sectional view taken along line X-X of FIG. 1. Through the electrical connection among the shielding cover 6, the first metal layer 43, and the buffering conductor 3, the shielding cover 6 and its extension tabs 61 form a closed loop with the first metal layer 43 in both the XY and YZ planes (in FIG. 1 and FIG. 10), thereby completely enclosing the first connector 2 and the second connector 5 and achieving a three-dimensional electrical shielding effect.

When the second connector 5 is mated with the first connector 2, the second circuit board 4 presses downward through its side edge 4S against the buffering conductor 3, causing the buffering conductor 3 to deform and extend laterally toward both the first surface 41 and the second surface 42. The portion of the buffering conductor 3 extending to the first surface 41 further contacts and covers the first metal extending portion 431, and the portion of the buffering conductor 3 extending to the second surface 42 further contacts and covers the second metal extending portion 432. Through the design of the first metal extension portion 431 and the second metal extension portion 432, the contact area between the buffering conductor 3 and the first metal layer 43 can be increased, thereby further enhancing the electrical shielding effect.

As shown in FIGS. 2 and 10, the second circuit board 4 presses downward through its side edge 4S against the buffering conductor 3 along a Z-axis, and the contact surface between the first metal layer 43 and the buffering conductor 3 is a continuous surface without interruption. Accordingly, the first metal layer 43 and the shielding cover 6 jointly enclose the first connector 2 and the second connector 5 to achieve complete electrical shielding effect without weak spots. Additionally, the projection of the first metal layer 43 onto the upper surface 3U of the buffering conductor 3 may either lie entirely within or partially exceed the area of the upper surface 3U. In other words, the relative position of the first metal layer 43 on the upper surface 3U of the buffering conductor 3 can be adjusted along a Y-axis according to design requirements, as long as the contact surface between the first metal layer 43 and the buffering conductor 3 remains continuous to achieve the electrical shielding effect.

### [Beneficial Effects of the Embodiment]

In the related art, since the connectors (i.e., the first connector 2 and the second connector 5) of the board-end connectors (i.e., the first board-end connector M1 and the second board-end connector M2) are disposed at the edge of the circuit boards, the shielding cover cannot fully enclose the connectors, resulting in shielding gaps in the board-end connectors facing the circuit boards. Therefore, through the structural design of the first metal layer 43 on the side edge of the second circuit board 4 in cooperation with the shielding cover 6, the first metal layer 43 and the shielding cover 6 jointly enclose the first connector 2 and the second connector 5, so as to enhance the effect of electrical shielding and address the issue in the related art where mere reliance on the shielding cover for shielding tends to result in signal interference gaps.

Furthermore, the extension tabs 61 of the shielding cover 6 can enlarge the contact area with the buffering conductor 3, which not only enhances the structural strength of the shielding cover 6 on the buffering conductor 3, but also increases the electrical contact area between the shielding cover 6 and the buffering conductor 3, thereby enhancing the shielding effect. Moreover, since the buffering conductor 3 is compressible, the second circuit board 4 moves downward during mating of the second connector 5 with the first connector 2 and contacts the buffering conductor 3. The buffering conductor 3 is compressed and provides a buffering stroke to prevent direct contact with the first circuit board 1, so as to avoid mechanical interference and ensure stable mating between the second connector 5 and the first connector 2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A board-to-board connector assembly with a shielding structure, comprising:
a first circuit board;
a first connector disposed on the first circuit board;
a buffering conductor disposed on the first circuit board and surrounding the first connector;
a second circuit board being perpendicular to the first circuit board, wherein a side edge of the second circuit board is provided with a first metal layer;
a second connector disposed on the second circuit board, wherein the second connector is configured to be mated with the first connector along a mating direction; and
a shielding cover disposed on the second circuit board and surrounding the second connector;
wherein, when the second connector is mated with the first connector along the mating direction, the side edge of the second circuit board abuts against the buffering conductor, such that the first metal layer is electrically connected to the buffering conductor, and the shielding cover encloses the first connector.

2. The board-to-board connector assembly according to claim 1, wherein the shielding cover is electrically connected to the first metal layer, and the shielding cover has an opening.

3. The board-to-board connector assembly according to claim 2, wherein the shielding cover includes an extension tab extending from an edge of the opening, and the extension tab is bent outward from the opening.

4. The board-to-board connector assembly according to claim 3, wherein a width of the first metal layer is greater than or equal to a width of the extension tab.

5. The board-to-board connector assembly according to claim 3, wherein an edge of the extension tab is flush with the side edge of the second circuit board.

6. The board-to-board connector assembly according to claim 3, wherein the extension tab extends along a periphery of the opening and abuts against an upper surface of the buffering conductor when the shielding cover encloses the first connector.

7. The board-to-board connector assembly according to claim 6, wherein, when the extension tab abuts against the upper surface of the buffering conductor, a projection of the extension tab that is projected onto the upper surface does not exceed the upper surface.

8. The board-to-board connector assembly according to claim 1, wherein the second circuit board has a first surface and a second surface that are opposite to each other, the side edge of the second circuit board is connected between the first surface and the second surface, the first metal layer includes a first metal extending portion and a second metal extending portion, the first metal extending portion extends to the first surface, and the second metal extending portion extends to the second surface.

9. The board-to-board connector assembly according to claim 8, wherein, when the second connector is mated with the first connector along the mating direction, the side edge of the second circuit board presses the buffering conductor downward, such that the buffering conductor is compressed and deformed, extends to the first surface and the second surface, and further covers the first metal extending portion and the second metal extending portion.

10. The board-to-board connector assembly according to claim 8, wherein a width of each of the first metal extending portion and the second metal extending portion ranges from 0.5 mm to 1 mm.

11. The board-to-board connector assembly according to claim 10, wherein the second circuit board further includes a second metal layer that is connected to the first metal layer, and the shielding cover is soldered to the second metal layer.

12. The board-to-board connector assembly according to claim 11, wherein the second metal layer surrounds the second connector, the second metal layer has two ends, and a solder resist layer is provided between a surface of each of the two ends and a surface of the first metal layer.

13. The board-to-board connector assembly according to claim 11, wherein the second metal layer surrounds the second connector, the second metal layer has two ends, and a solder resist layer is provided between a surface of each of the two ends and a surface of the first metal extending portion.

14. The board-to-board connector assembly according to claim 13, wherein a width of the solder resist layer is greater than 0.1 mm.

15. The board-to-board connector assembly according to claim 1, wherein a metal grounding layer is provided on a surface of the first circuit board, the metal grounding layer surrounds the first connector, and the buffering conductor is disposed on the metal grounding layer.
